(19) United States
(12) Patent Application Publication
(10) Pub. No.: US 2010/0027205 A1
(43) Pub. Date: Feb. 4, 2010

(54) COMPUTER FRONT BEZEL

(75) Inventor: XIANG CAO, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (SHENZHEN) CO., LTD., Shenzhen City (CN); HON HAI PRECISION INDUSTRY CO., LTD., Tu-Cheng (TW)

(21) Appl. No.: 12/275,218

(22) Filed: Nov. 21, 2008

(30) Foreign Application Priority Data
Jul. 31, 2008 (CN) 200810303290.1

(51) Int. Cl. H05K 5/03

(52) U.S. Cl. 361/679.6

(57) ABSTRACT

A computer front bezel is made of color-changeable material, or includes a layer of color-changeable material attached to an out surface of the bezel. The color-changeable material includes a mixture of a heat-sensitive color-changing material and a plastic material.

### BACKGROUND

1. Technical Field

The disclosure relates to bezels and, particularly, to a computer front bezel.

2. Description of Related Art

Nowadays, a large number of personal computers are sold for home use. The appearance of a computer has become an important selling point.

### BRIEF DESCRIPTION OF THE DRAWINGS

FIG. 1 is a front view of a front bezel for a computer case in accordance with one exemplary embodiment.

FIG. 2 is a cross-sectional view taken along the line II-II of FIG. 1.

### DETAILED DESCRIPTION

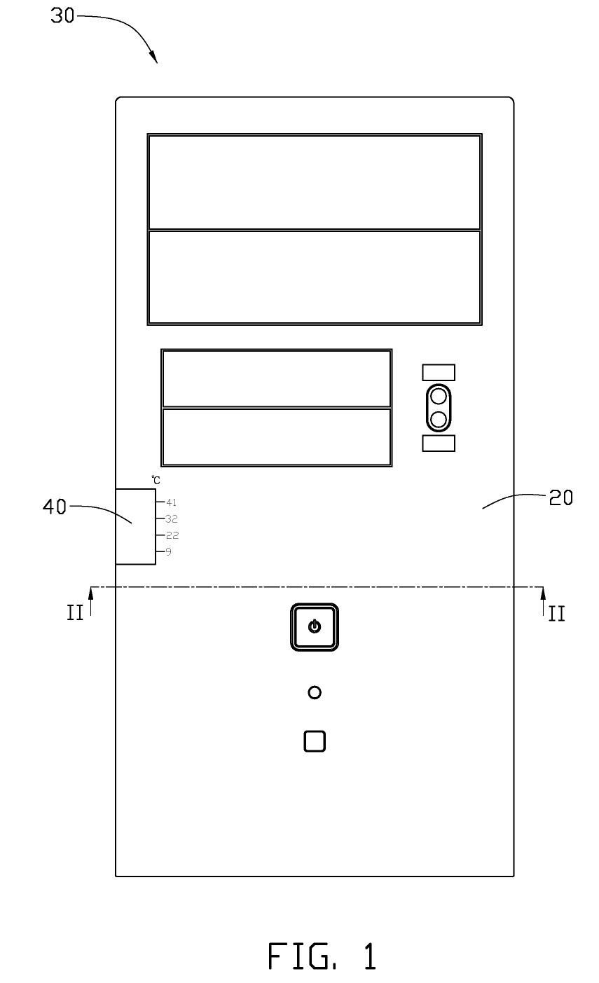

Referring to FIG. 1, an exemplary embodiment of a front bezel 30 for a computer case (not shown) is provided. The bezel 30 includes a layer of color-changeable material or is entirely made of color-changeable material. The color-changeable material includes a mixture, according to a given ratio, of a heat-sensitive color-changing material and a plastic material.

The plastic material may be one or more kinds of material selected from acrylonitrile butadiene styrene (ABS), polycarbonate (PC), polypropylene (PP). In one embodiment, ABS is selected.

In this embodiment, the heat-sensitive color-changing material is thermochromic powder whose color fades as its temperature rises. In other words, the color of the thermochromic powder is obvious at low temperatures, and fades to translucency when the temperature rises to a set temperature.

In producing the color-changeable mixture, ABS grains and the thermochromic powder are mixed together, then molded via injection molding or extrusion molding. The mass ratio of the ABS grains to the thermochromic powder is about 1000:4 to about 1000:40, herein 1000:30 is used.

In this embodiment, the thermochromic powder includes white, blue, yellow, and red thermochromic powders. The four colors of powders are used together with the ABS grains to produce the color-changeable material. The mass ratio of the white, blue, yellow, and red thermochromic powders is about 1:1:1:1.

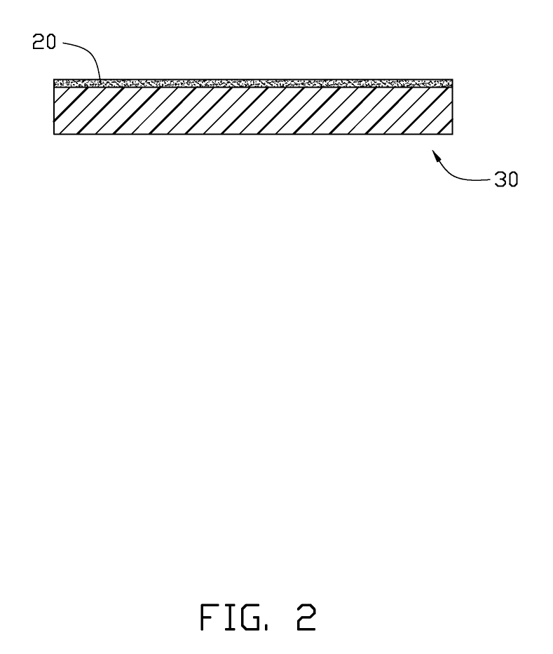

Referring to FIG. 2, in this embodiment, a layer of the color-changeable material is molded into a layer 20 and attached to the bezel 30. The set temperatures of the white, blue, yellow, and red thermochromic powders are 9° C., 22° C., 32° C., and 41° C. respectively. When temperature of the color changeable material is lower than 9° C., all the colors of white, blue, yellow and red are visible and mix to make the bezel 30 appear grey; when the temperature is 9° C. or higher, but less than 22° C., the white becomes translucent, and the blue, yellow, and red mix to make the bezel 30 appear black; when the temperature is 22° C. or higher, but less than 32° C., the white and blue becomes translucent as well, and the yellow and red mix to make the bezel 30 appear orange; when the temperature is 32° C. or higher, but less than 41° C., the yellow also becomes translucent, and the bezel 30 appears red; and when the temperature is 41° C. or higher, all the colors are translucent, and the bezel 30 appears the color of the ABS, which is translucent.

Although in use the temperature of the bezel 30 may be lower than the temperature in the computer case, relationship between the colors of the bezel 30 and the internal temperature can be easily determined and made known to users by use of a color coded chart attached to the bezel 30. Moreover, other temperatures besides 9° C., 22° C., 32° C., and 41° C. can be selected as desired according to the thermochromic powders selected.

Further, the bezel 30 may also include a color-temperature label 40 (see FIG. 1), for showing a relationship between the color of the bezel 30 and the temperature in the computer case. The bezel 30 makes it convenient for the temperature of the computer system to be known, so that users may take action should their system become overheated.

In other embodiments, the mass ratio of the white, blue, yellow, and red thermochromic powder may be adjusted, thus adjusting the apparent colors of the bezel 30 at different temperatures. Different or additional colors may be selected according to thermochromic powders selected as well.

It is believed that the present embodiments and their advantages will be understood from the foregoing description, and it will be apparent that various changes may be made thereto without departing from the spirit and scope of the invention or sacrificing all of its material advantages, the examples hereinbefore described merely being exemplary embodiments of the disclosure.

What is claimed is:

1. A computer front bezel comprising of color-changeable material or comprising a layer of color-changeable material at the outmost portion thereof, wherein the color-changeable material comprising a mixture of a heat-sensitive color-changing material and a plastic material.

2. The bezel of claim 1, wherein the heat-sensitive color-changing material is thermochromic powder.

3 The bezel of claim 2, wherein the thermochromic powder is a material whose color is most prominent at low temperatures and fades to translucency as the temperature rises to a set temperature.

4. The bezel of claim 2, wherein the plastic material is at least one kind of material selected from acrylonitrile butadiene styrene, polycarbonate, and polypropylene.

5. The bezel of claim 3, wherein the plastic material is acrylonitrile butadiene styrene grains.

6. The bezel of claim 5, wherein the mass ratio of the acrylonitrile butadiene styrene grains to the thermochromic powder is about 1000:4 to about 1000:40.

7. The bezel of claim 5, wherein the mass ratio of the acrylonitrile butadiene styrene grains to the thermochromic powder is 1000:30.

8. The bezel of claim 6, wherein the color-changeable material is produced via injection molding or extrusion molding.

9. The bezel of claim 6, wherein the heat-sensitive color-changing material comprises white, blue, yellow, and red thermochromic powder, and the plastic material is translucent.

10. The bezel of claim 9, wherein the mass ratio of the white, blue, yellow, and red thermochromic powder is about 1:1:1:1.

11. The bezel of claim 9, wherein the set temperatures of the white, blue, yellow, and red thermochromic powder are 9° C., 22° C., 32° C., and 41° C., respectively.

12. The bezel of claim 11, further comprising a color-temperature label, for showing an relationship between the color of the bezel and the temperature in a computer case that the bezel is attached to.

13. A computer case, comprising:
a front bezel made of color-changeable material, wherein the color-changeable material comprising a mixture of a heat-sensitive color-changing material and a plastic material.

14. The computer case of claim 13, wherein the heat-sensitive color-changing material is thermochromic powder.

15. The computer case of claim 14, wherein the thermochromic powder is a material whose color is most prominent at low temperatures and fades to translucency as the temperature rises to a set temperature.

16. A computer case, comprising:
a front bezel comprising a layer of color-changeable material at the outmost portion thereof, wherein the color-changeable material comprising a mixture of a heat-sensitive color-changing material and a plastic material.

17. The computer case of claim 16, wherein the heat-sensitive color-changing material is thermochromic powder.

18. The computer case of claim 17, wherein the thermochromic powder is a material whose color is most prominent at low temperatures and fades to translucency as the temperature rises to a set temperature.
